(19) United States
(12) Patent Application Publication
(10) Pub. No.: US 2025/0261454 A1
(43) Pub. Date: Aug. 14, 2025

(54) SOLAR CELLS HAVING THERMALLY CONDUCTIVE MULTILAYERED STRUCTURES

(71) Applicant: The Boeing Company, Arlington, VA (US)

(72) Inventors: Christopher Michael Fetzer, Valencia, CA (US); Eric M. Rehder, Los Angeles, CA (US); Vytas Thomas Gylys, Bell Canyon, CA (US)

(21) Appl. No.: 19/048,706

(22) Filed: Feb. 7, 2025

Related U.S. Application Data
(60) Provisional application No. 63/551,335, filed on Feb. 8, 2024.

(51) Int. Cl. H10F 19/80; H10F 77/30; H10F 77/63

(52) U.S. Cl. CPC H10F 19/80; H10F 77/315; H10F 77/63

(57) ABSTRACT

Solar cells having thermally conductive multilayered structures are disclosed. A disclosed thermally conductive structure for use with a solar panel includes an at least partially transparent coverslide including at least one of amorphous glass material, a crystalline material or a crystal material.

### RELATED APPLICATION

This patent claims the benefit of U.S. Provisional Patent Application No. 63/551,335, which was filed on Feb. 8, 2024. U.S. Provisional Patent Application No. 63/551,335 is hereby incorporated herein by reference in its entirety. Priority to U.S. Provisional Patent Application No. 63/551,335 is hereby claimed.

### FIELD OF THE DISCLOSURE

This disclosure relates generally to solar cells and, more particularly, to solar cells having thermally conductive multilayered structures.

### BACKGROUND

Typically, solar cells of arrays in space convert approximately 30% of power corresponding to incident sunlight into usable electrical power, and the remaining 70% of the power is converted/transferred into heat that is radiated back into space. With such a distribution, transfer and/or transmission of power, cells of a solar array can reach an equilibrium temperature under normal operation of approximately 60° Celsius (C) to 80° C. Accordingly, an increased temperature can result in lower output power.

### SUMMARY

An example thermally conductive structure for use with a solar pane includes an at least partially transparent coverslide having at least one of an amorphous glass material, a crystalline material or a crystal material.

An example coverglass interconnect cell (CIC) includes an at least partially transparent coverslide having at least one of an amorphous glass material, a crystalline material or a crystal material, an ultraviolet reflective coating, an at least partially transparent adhesive, and a cell coupled to the at least partially transparent adhesive.

An example method of producing a coverglass interconnect cell (CIC) includes coupling an antireflective coating to a first side of an at least partially transparent coverslide, the coverslide including at least one of an amorphous glass material, a crystalline material or a crystal material, and coupling an ultraviolet reflective coating to a second side of the coverslide opposite the first side.

### BRIEF DESCRIPTION OF THE DRAWINGS

FIG. 1 is a portion of an example solar array in which examples disclosed herein can be implemented.

FIG. 2 is a cross-sectional view of a known layered structure.

FIG. 3 is a cross-sectional view of an example layered structure constructed in accordance with teachings of this disclosure.

FIG. 4 is a flowchart representative of an example method to produce examples disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Solar cells having thermally conductive multilayered structures are disclosed. Known solar arrays utilize cells that convert incident sunlight into electrical power. However, the solar array being positioned in space can pose challenges in maintaining a heat distribution and/or temperatures thereof. In particular, a lack of heat transfer in space can significantly reduce an ability of a structure to dissipate heat. As a result, temperatures of a solar array can exceed operating and/or specification limits and, thus, performance may be reduced.

In known implementations, measures are implemented to increase a thermal conductance to dissipate heat to a substrate of a solar array. In particular, the aforementioned substrate can support photo-voltaic cells and dissipate heat from the cells to manage a heat distribution of the solar array. The thermal conductance of the substrate is usually based on a fully-bonded silicone room temperature vulcanizing (RTV) layer that is positioned under/beneath a respective cell of the solar array. In some situations, it can be advantageous to use a reduced amount of silicone RTV because manufacturing defects can trap air in voids beneath the cell. Accordingly, cells that are bonded with a pattern of adhesive can experience relatively higher operating temperatures and, thus, decreased thermal performance. Additionally, a germanium (Ge) substrate can act as a thermal conductor or heat-spreader and thinning of a Ge substrate and/or sub-cell can reduce a mass of a corresponding solar array and, thus, an overall mass of a satellite. However, such a reduction of mass can also increase cell temperatures and, thus, reduce performance thereof.

Examples disclosed herein enable increased heat removal capabilities of a solar panel and/or a solar array. Examples disclosed herein can reduce manufacturing defects of solar arrays and/or panels, thereby increasing yields thereof and, thus, reducing costs. Examples disclosed herein can also advantageously reduce a weight of the solar array by reducing a necessitated amount of the aforementioned silicone RTV and can additionally reduce a necessitated volume and, thus, weight of the germanium substrate, for example.

Examples disclosed herein utilize a thermally conductive layered structure with an at least partially transparent coverslide (e.g., a coverglass, an at least partially transparent coverslide, etc.) that includes an amorphous glass material, a crystalline material or a crystal material. In some examples, the coverslide includes a crystalline material. According to examples disclosed herein, the layered structure includes an antireflective coating on a first side of the coverslide and an ultraviolet reflective coating on a second side of the coverslide opposite the first side. According to some examples disclosed herein, an external surface of the antireflective coating faces toward a direction of incident light with respect to the layered structure. Further, the layered structure includes a cell that is operatively coupled to (e.g., adhered to) the ultraviolet reflective coating. In turn, the cell is bonded to an insulator and/or substrate with an adhesive (e.g., a bonded adhesive), which can be a silicone RTV adhesive. According to some examples disclosed herein, the adhesive that bonds the cell to the insulator and/or the substrate is patterned (e.g., applied as a pattern) with walls separated by gaps (e.g., a rectangular grid of the adhesive), thereby saving weight.

According to some examples disclosed herein, the layered structure is part of a solar panel. In some such examples, the solar panel can be part of a satellite. In some examples, the cell includes a substrate, which can be at least partially composed of germanium. In some examples, the coverslide includes at least one of sapphire, aluminum oxide, silicon carbide, gallium nitride, aluminum nitride, yttrium aluminum garnet (YAG) (e.g., undoped YAG, or calcium fluoride (or any other appropriate material). Additionally or alternatively, the coverslide is approximately 50 micrometers (μm) to 875 μm in thickness (e.g., 50 μm to 100 μm, 50 μm to 150 μm, 75 μm to 100 μm, 75 μm to 150 μm, 400 μm to 500 μm, etc.).

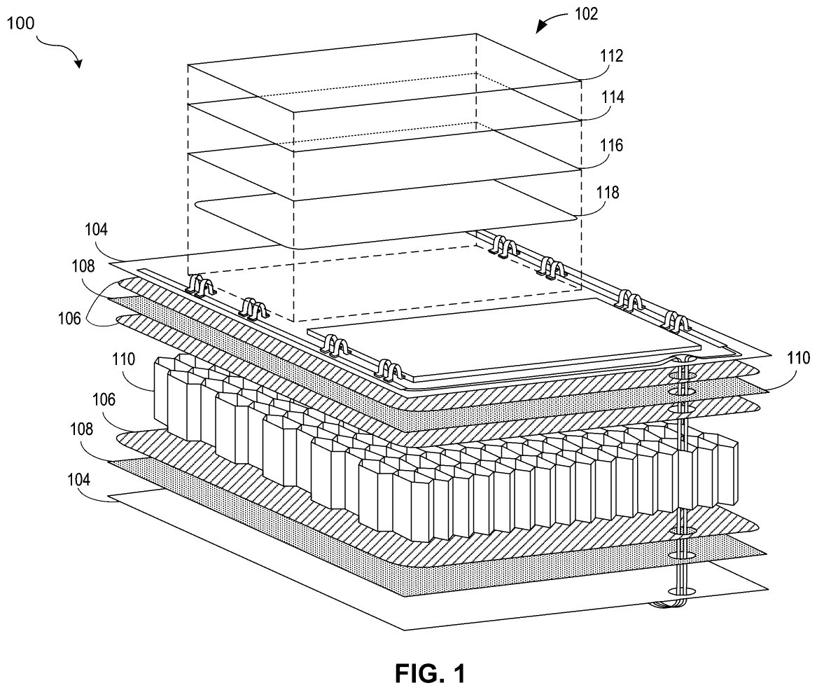

FIG. 1 is a portion of an example solar array 100 in which examples disclosed herein can be implemented. The solar array 100 of the illustrated example includes a coverglass interconnect cell (CIC) 102, insulators (e.g., insulator layers) 104, adhesive layers 106, facesheets 108 and a core 110. In turn, the example CIC 102 includes a coverglass 112, a transparent adhesive 114, a cell (e.g., a photovoltaic cell) 116 and an adhesive (e.g., an adhesive layer) 118. In this example, two of the CICs 102 are mounted and/or coupled to the insulator 104. In other words, the insulator 104 supports the CICs 102. However, any other appropriate number of the CICs 102 can be implemented instead (e.g., one, three, four, five, . . . ten, . . . twenty, etc.).

In operation, the CICs 102 convert and/or transfer power from incident solar rays to electrical power. However, this conversion process can yield heat based on an inefficiency thereof. As a result, the CICs 102 can experience a significant increase in temperature, which can result in decreased performance of the same. In contrast, some examples disclosed herein can increase a thermal conductivity of a CIC by utilizing an at least partially transparent (e.g., fully transparent) layer, coverglass and/or coverslide that is at least partially composed of a crystalline material, for example. Further, a UV reflector can be utilized to further reduce temperatures of the CIC. Examples disclosed herein can also reduce and/or eliminate a need to fully apply an adhesive between the CIC and a supporting substrate and/or an insulator, which can increase yields as well as reduce weight.

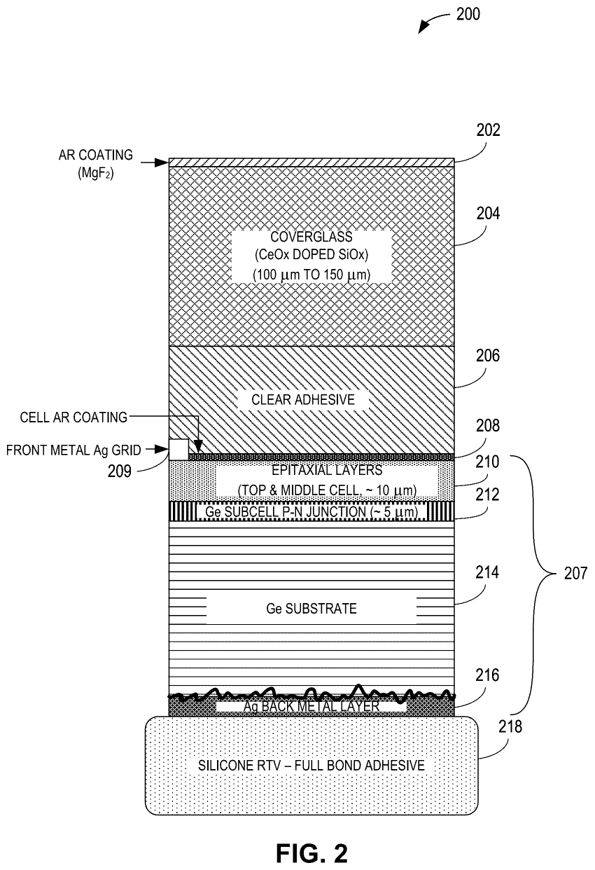

FIG. 2 is a cross-sectional view of a known layered structure 200. In the illustrated view, the known layered structure 200 includes an antireflective (AR) coating 202, a coverglass 204, an at least partially transparent adhesive 206, and a cell 207. In turn, the cell 207 includes a cell AR coating 208, a metal grid (e.g., a front metal grid) 209, epitaxial layers 210, a subcell (e.g., a subcell P-N junction, etc.) 212, a substrate 214, and a metal layer (e.g., a back metal layer, a metal backing, etc.) 216. Further, the layered structure 200 is bonded to the insulator 104 (of FIG. 1) with an adhesive (e.g., an adhesive layer, a full bond adhesive, etc.) 218.

In known systems, the AR coating 202 includes magnesium fluoride and the coverglass 204 is at least partially composed of glass, ceria, a ceria doped microsheet and/or ceria dioxide (CeOx). The ceria dioxide can be doped with silicon oxide (SiOx), for example. In this known implementation, the coverglass 204 is approximately 100 μm to 150 μm thick. Further, the adhesive 206, which may be implemented as a silicone adhesive, such as the commercially available Dow® DC93-500 adhesive, is approximately 50 μm thick while the metal grid 209 includes silver. The epitaxial layers 210 are approximately 5-15 μm thick. The subcell 212, which acts a p-n junction, includes germanium and is 2-8 μm in thickness. Further, the substrate 214 includes germanium with a thickness of approximately 100-200 μm. In this known implementation, the adhesive 218 is accurately controlled to cover an entire lateral span (e.g., a planar span) of the layered structure 200 without a significant amount of gaps, etc. because inconsistencies thereof can result in reduced thermal performance. To that end, the adhesive application is controlled for uniformity and to an entire lateral span (left and right in the view of FIG. 2) of the layered structure 200. In contrast, examples disclosed herein can increase a thermal outflux/performance and do not necessitate complete and/or extensive planar/layered application of the adhesive 218 to maintain temperatures. Some examples disclosed herein can instead utilize a partial and/or patterned adhesive application (e.g., a checkerboard pattern, a striped pattern, etc.).

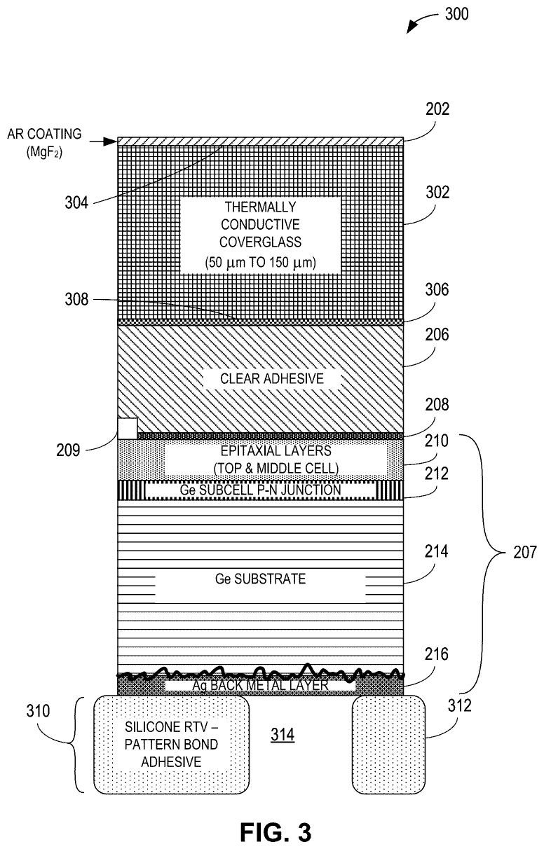

FIG. 3 is a cross-sectional view of an example layered structure 300 constructed in accordance with teachings of this disclosure. The example layered structure 300 may be implemented in the CIC 102 and/or the solar array 100 shown in FIG. 1. Similar to the layered structure 200 of FIG. 2, the example layered structure 300 includes the AR coating 202, the transparent adhesive 206, and the cell 207 which, in turn, includes the cell AR coating 208, the metal grid 209, epitaxial layers 210, the subcell 212, the substrate 214, and the metal layer 216.

According to examples disclosed herein, to increase a thermal conductivity of the layered structure 300, the layered structure 300 includes a thermally conductive coverslide (e.g., a coverglass, a non-silicon oxide coverglass, a coverslide layer, a thermally conductive coverslide, etc.) 302. In this example, the aforementioned AR coating 202 is at a first side 304 of the coverslide 302 and a UV reflective coating 306 is at a second side 308 of the coverslide 302 that is opposite to the first side 304. In other words, the AR coating 202 and the UV reflective coating 306 are on opposing sides of the coverslide 302. According to examples disclosed herein, material of the coverslide 302 has sufficient transparency (e.g., transparent between 0.3 μm and 1.8 um) for multijunction solar cells along with relatively smooth optical surface. In some examples, the material of the coverslide 302 can have a thermal conductivity greater than the 1 Watt (W)/meter (m) Kelvin (K) of standard glass along with a coefficient of thermal expansion (CTE) that may be closely matched to that of a multijunction solar cell (typically near 5 ppm/C). The material of the coverslide 302 can also be resistance to typical production processes (water, handling, coating, temperatures, etc.) with durability for a space environment that can include atomic oxygen, charged particle radiation (protons and electrons), as well as UV exposure with minimal darkening.

To advantageously reduce weight, an adhesive (e.g., a bond adhesive, an adhesive layer, a patterned adhesive layer, an RTV adhesive, etc.) 310 is applied/coupled/defined as a pattern, thereby defining portions (e.g., walls, webs, spans, etc.) 312 separated by gaps 314 therebetween. In contrast to the application of the adhesive 218 shown in FIG. 2, the increased conductivity of the coverslide 302 does not necessitate a full and/or complete application of adhesive, as typically required in known layered structures. As a result, significant weight reductions can be realized using examples disclosed herein. Further, examples disclosed herein can reduce weight by enabling the substrate 214 to be thinner than typical known implementations due to the increased conductivity of the coverslide 302. In other words, examples disclosed herein are not dependent on full application of the adhesive 310 for sufficient thermal conduction. In this example, the coverslide 302 does not include silicon oxide (SiOx).

In some examples, the adhesive 310 is applied, placed and/or defined as a grid (e.g., a square grid pattern, a circle grid pattern, a hexagonal grid pattern, an irregular pattern, etc.). Additionally or alternatively, the portions 312 can define a cell pattern (e.g., an oval cell pattern, a hexagonal cell pattern, a rectangular cell pattern, etc.). According to some examples disclosed herein, the adhesive 310 is applied to define a pattern of cells having varying sizes (e.g., cells on lateral ends of the layered structure 300 are larger than cells closer to a center of the layered structure 300 and vice-versa). In some examples, a conductive coating, such as indium tin oxide, is utilized as a reflective coating for the AR coating 202.

According to some examples disclosed herein, the coverslide 302 includes at least one of sapphire, aluminum oxide, silicon carbide, gallium nitride, aluminum nitride, yttrium aluminum garnet, or calcium fluoride. In some examples, the coverslide 302 includes and/or is at least partially composed diamond and/or a diamond-like material. However, any other materials and/or layering implementations can be implemented instead. Additionally or alternatively, the example coverslide 302 is approximately 50 μm to 150 μm in thickness (e.g., 50 μm to 100 μm in thickness. 75 μm to 100 μm in thickness).

In some examples, the metal layer 216 and/or thermal conductance layer (substrate) are implemented as a backside addition (below the substrate 214 as viewed in FIG. 3) as a heat spreader that may be composed of multiple layers. Some of the substrates can support epitaxial and polycrystalline deposited materials that cannot typically be formed as stand-alone coverslides. An example is gallium nitride (GaN) on silicon carbide (SiC), which is used as a base for light emitting diode (LED)/laser diode (LD) formation. Another example is diamond layers grown on aluminum oxide/alumina (Al₂O₃) substrates that can be implemented in examples disclosed herein.

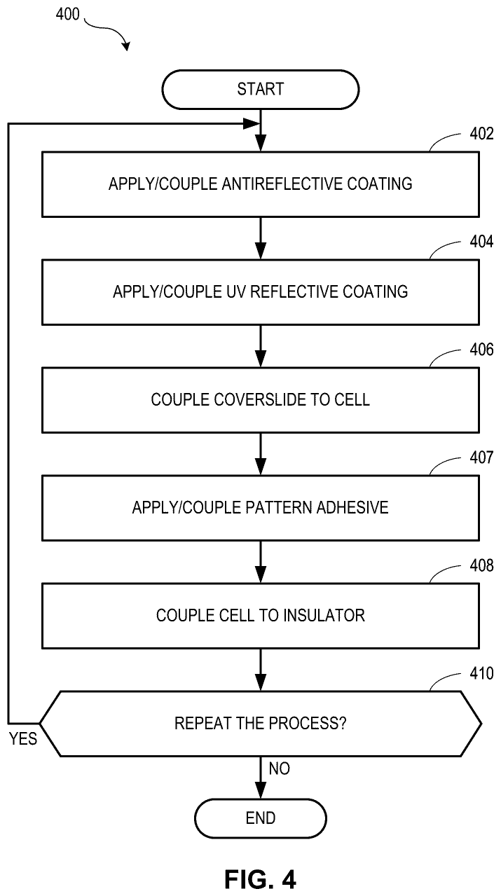

FIG. 4 is a flowchart representative of an example method 400 to produce examples disclosed herein. The example method 400 is utilized to produce the layered structure 300 for use with and/or to define a CIC (e.g., the CIC 102) of a solar array (e.g., the solar array 100) of a satellite, for example. The example method 400 of the illustrated example begins at block 402 as the AR coating 202 is applied to the coverslide 302 at the first side 304 of the coverslide 302.

At block 404, the UV reflective coating 306 is applied and/or coupled to the coverslide 302 at the second side 308 of the coverslide 302.

At block 406, according to examples disclosed herein, the coverslide 302 is coupled to the cell 207 with the adhesive 206. In some examples, the adhesive 206 is approximately 50 μm in thickness.

At block 407, the adhesive 310 is applied and/or patterned to the cell 207 and/or the substrate 214 supporting the cell 207. According to some examples disclosed herein, the adhesive 310 is applied as a grid-like pattern to the cell 207 and/or the substrate 214. Additionally or alternatively, the adhesive 310 is patterned onto the insulator 104.

At block 408, the cell 207 (along with the coverslide 302) is coupled to an insulator (e.g., the insulator 104), a surface and/or a substrate (e.g., a support substrate) of the solar cell with the adhesive 310.

At block 410, it is determined whether to repeat the process. If the process is to be repeated (block 410), control of the process returns to block 402. Otherwise, the process ends. The determination may be based on whether additional CICs and/or solar arrays are to be produced.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

Example methods, apparatus, systems, and articles of manufacture to enable increased performance of thermal panels are disclosed herein. Further examples and combinations thereof include the following:

Example 1 includes a thermally conductive structure for use with a solar panel, the thermally conductive structure comprising an at least partially transparent coverslide including at least one of an amorphous glass material, a crystalline material or a crystal material.

Example 2 includes the thermally conductive structure as defined in example 1, further including an antireflective coating.

Example 3 includes the thermally conductive structure as defined in example 1, further including an ultraviolet reflective coating.

Example 4 includes the thermally conductive structure as defined in example 3, further including an at least partially transparent adhesive to couple the ultraviolet reflective coating to a cell.

Example 5 includes the thermally conductive structure as defined in example 1, further including bond adhesive to couple the thermally conductive structure to an insulator of the solar panel.

Example 6 includes the thermally conductive structure as defined in example 5, wherein the bond adhesive is applied as a pattern.

Example 7 includes the thermally conductive structure as defined in example 6, wherein the pattern is a grid pattern.

Example 8 includes the thermally conductive structure as defined in example 1, wherein the coverslide includes at least one of sapphire, aluminum oxide, silicon carbide, gallium nitride, aluminum nitride, yttrium aluminum garnet, or calcium fluoride.

Example 9 includes the thermally conductive structure as defined in example 1, wherein the coverslide is approximately 50 micrometers (μm) to 875 μm in thickness.

Example 10 includes a coverglass interconnect cell (CIC) comprising an at least partially transparent coverslide including at least one of an amorphous glass material, a crystalline material or a crystal material, an ultraviolet reflective coating, an at least partially transparent adhesive, and a cell coupled to the at least partially transparent adhesive.

Example 11 includes the CIC as defined in example 10, further including an antireflective coating.

Example 12 includes the CIC as defined in example 10, wherein the at least partially transparent adhesive couples the ultraviolet reflective coating to a second antireflective coating of the cell.

Example 13 includes the CIC as defined in example 10, further including a patterned layer of bond adhesive to couple the CIC to an insulator of a solar panel.

Example 14 includes the CIC as defined in example 13, wherein the patterned layer of bond adhesive defines gaps between the cell and the insulator of the solar panel.

Example 15 includes the CIC as defined in example 10, wherein the coverslide includes at least one of sapphire, aluminum oxide, silicon carbide, gallium nitride, aluminum nitride, yttrium aluminum garnet, or calcium fluoride.

Example 16 includes the CIC as defined in example 10, wherein the cell includes a germanium subcell.

Example 17 includes the CIC as defined in example 16, wherein the germanium subcell defines a p-n junction.

Example 18 includes a method of producing a coverglass interconnect cell (CIC), the method comprising coupling an antireflective coating to a first side of an at least partially transparent coverslide, the coverslide including at least one of an amorphous glass material, a crystalline material or a crystal material, and coupling an ultraviolet reflective coating to a second side of the coverslide opposite the first side.

Example 19 includes the method as defined in example 18, further including applying an at least partially transparent adhesive to the ultraviolet reflective coating to couple a cell to the ultraviolet reflective coating.

Example 20 includes the method as defined in example 18, further including applying a pattern of bonding adhesive to bond the CIC to an insulative substrate.

From the foregoing, it will be appreciated that example systems, apparatus, articles of manufacture, and methods have been disclosed that enable increased thermal performance of solar cells. Examples disclosed herein can be cost-effective to produce and/or manufacture. Examples disclosed herein can also increase production yields by removing and/or eliminating a need for a highly controlled application and/or curing of adhesive with respect to bonding a coverslide, coverglass and/or a CIC. Examples disclosed herein can also advantageously enable reduced weight by not necessitating a full application of adhesive for a cell, which is typically required to satisfy thermal performance requirements.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A thermally conductive structure for use with a solar panel, the thermally conductive structure comprising:
an at least partially transparent coverslide including at least one of an amorphous glass material, a crystalline material or a crystal material.

2. The thermally conductive structure as defined in claim 1, further including an antireflective coating.

3. The thermally conductive structure as defined in claim 1, further including an ultraviolet reflective coating.

4. The thermally conductive structure as defined in claim 3, further including an at least partially transparent adhesive to couple the ultraviolet reflective coating to a cell.

5. The thermally conductive structure as defined in claim 1, further including bond adhesive to couple the thermally conductive structure to an insulator of the solar panel.

6. The thermally conductive structure as defined in claim 5, wherein the bond adhesive is applied as a pattern.

7. The thermally conductive structure as defined in claim 6, wherein the pattern is a grid pattern.

8. The thermally conductive structure as defined in claim 1, wherein the coverslide includes at least one of sapphire, aluminum oxide, silicon carbide, gallium nitride, aluminum nitride, yttrium aluminum garnet, or calcium fluoride.

9. The thermally conductive structure as defined in claim 1, wherein the coverslide is approximately 50 micrometers (μm) to 875 μm in thickness.

10. A coverglass interconnect cell (CIC) comprising:
an at least partially transparent coverslide including at least one of an amorphous glass material, a crystalline material or a crystal material;
an ultraviolet reflective coating;
an at least partially transparent adhesive; and
a cell coupled to the at least partially transparent adhesive.

11. The CIC as defined in claim 10, further including an antireflective coating.

12. The CIC as defined in claim 10, wherein the at least partially transparent adhesive couples the ultraviolet reflective coating to a second antireflective coating of the cell.

13. The CIC as defined in claim 10, further including a patterned layer of bond adhesive to couple the CIC to an insulator of a solar panel.

14. The CIC as defined in claim 13, wherein the patterned layer of bond adhesive defines gaps between the cell and the insulator of the solar panel.

15. The CIC as defined in claim 10, wherein the coverslide includes at least one of sapphire, aluminum oxide, silicon carbide, gallium nitride, aluminum nitride, yttrium aluminum garnet, or calcium fluoride.

16. The CIC as defined in claim 10, wherein the cell includes a germanium subcell.

17. The CIC as defined in claim 16, wherein the germanium subcell defines a p-n junction.

18. A method of producing a coverglass interconnect cell (CIC), the method comprising:
coupling an antireflective coating to a first side of an at least partially transparent coverslide, the coverslide including at least one of an amorphous glass material, a crystalline material or a crystal material; and
coupling an ultraviolet reflective coating to a second side of the coverslide opposite the first side.

19. The method as defined in claim 18, further including applying an at least partially transparent adhesive to the ultraviolet reflective coating to couple a cell to the ultraviolet reflective coating.

20. The method as defined in claim 18, further including applying a pattern of bonding adhesive to bond the CIC to an insulative substrate.
